(19) United States
(12) Patent Application Publication
(10) Pub. No.: US 2026/0040976 A1
(43) Pub. Date: Feb. 5, 2026

(54) SEMICONDUCTOR PACKAGE

(71) Applicant: SAMSUNG ELECTRONICS CO., LTD., Suwon-si (KR)

(72) Inventors: Hyeonjeong HWANG, Suwon-si (KR); Kuwon LEE, Suwon-si (KR); Sehoon JANG, Suwon-si (KR)

(73) Assignee: SAMSUNG ELECTRONICS CO., LTD., Suwon-si (KR)

(21) Appl. No.: 19/276,554

(22) Filed: Jul. 22, 2025

(30) Foreign Application Priority Data
Jul. 30, 2024 (KR) 10-2024-0101126
Sep. 23, 2024 (KR) 10-2024-0128510

(51) Int. Cl. H01L 23/498; H01L 23/00; H01L 25/03; H01L 25/18; H10B 80/00; H10D 80/30

(52) U.S. Cl. CPC H01L 23/49838; H01L 23/49822; H01L 24/16; H01L 25/03; H01L 25/18; H10B 80/00; H10D 80/30; H01L 24/08; H01L 24/32; H01L 24/73; H01L 2224/08235; H01L 2224/1601; H01L 2224/16058; H01L 2224/16059; H01L 2224/16227; H01L 2224/16235; H01L 2224/32225; H01L 2224/73204

(57) ABSTRACT

Provided is a semiconductor package including a first wiring structure including a first wiring and a first wiring insulating layer on the first wiring, a first semiconductor chip on the first wiring structure, and a molding member on the first semiconductor chip, wherein the first wiring includes a first wiring via and a first wiring line, wherein the first wiring structure includes a first layer and a second layer, wherein the first wiring via is in each of the first layer and the second layer, the first wiring via in the first layer and the first wiring via in the second layer contact each other in a vertical direction, and wherein a size of the first wiring via in the first layer is less than a size of the first wiring via in the second layer.

### CROSS-REFERENCE TO RELATED APPLICATIONS

This application claims priority to Korean Provisional Patent Application No. 10-2024-0101126, filed on Jul. 30, 2024, and Korean Patent Application No. 10-2024-0128510, filed on Sep. 23, 2024, in the Korean Intellectual Property Office, the disclosures of which are incorporated by reference herein in their entireties.

### BACKGROUND

Embodiments of the present disclosure relate to a semiconductor package, and more particularly, to a semiconductor package including a stack via.

Recently, the demand for portable devices has been rapidly increasing in the electronic products market, and thus, there is continuous demand for miniaturization and weight reduction of electronic components installed in these electronic products. In order to reduce the size and weight of electronic components, semiconductor packages mounted on the electronic components are required to process high quantities of data while becoming increasingly reduced in size. Due to the miniaturization and weight reduction of semiconductor packages, connection failures may occur inside semiconductor packages.

### SUMMARY

One or more embodiments provide a semiconductor package in which a connection failure of a stack via is resolved and reliability is improved.

According to an aspect of one or more embodiments, there is provided a semiconductor package including a first wiring structure including a first wiring and a first wiring insulating layer surrounding the first wiring, a first semiconductor chip on the first wiring structure, and a molding member on the first semiconductor chip, wherein the first wiring includes a first wiring via and a first wiring line, wherein the first wiring structure includes a first layer and a second layer, wherein the first wiring via is in each of the first layer and the second layer, the first wiring via in the first layer and the first wiring via in the second layer contact each other in a vertical direction, and wherein a size of the first wiring via in the first layer is smaller than a size of the first wiring via in the second layer.

According to another aspect of one or more embodiments, there is provided a s semiconductor package including a first wiring structure including a first wiring and a first wiring insulating layer surrounding the first wiring, a first semiconductor chip on the first wiring structure, a conductive pillar on the first wiring structure and extending in a vertical direction, the conductive pillar being spaced apart from the first semiconductor chip in a horizontal direction, a molding member on the first semiconductor chip and the conductive pillar, a second wiring structure on the molding member and including a second wiring and a second wiring insulating layer on the second wiring, and a second semiconductor chip on the second wiring structure, wherein the first wiring includes a first wiring via and a first wiring line, wherein the first wiring structure includes a first layer and a second layer, wherein the first wiring via is in each of the first layer and the second layer, the first wiring via in the first layer and the first wiring via the second layer contact each other in the vertical direction, wherein a size of the first wiring via in the first layer is different from a size of the first wiring via in the second layer, wherein the second wiring includes a second wiring via and a second wiring line, wherein the second wiring structure includes a first layer and a second layer, wherein the second wiring via is in each of the first layer and the second layer, the second wiring via in the first layer and the second wiring via in the second layer contact each other in the vertical direction, and wherein a size of the second wiring via in the first layer is smaller than a size of the second wiring via in the second layer.

According to still another aspect of one or more embodiments, there is provided a semiconductor package including a first wiring structure including a first wiring and a first wiring insulating layer surrounding the first wiring, a first semiconductor chip on the first wiring structure, a conductive pillar on the first wiring structure and extending in a vertical direction, the conductive pillar being spaced apart from the first semiconductor chip in a horizontal direction, a molding member on the first semiconductor chip and the conductive pillar, a second wiring structure on the molding member and including a second wiring and a second wiring insulating layer on the second wiring, and a second semiconductor chip on the second wiring structure, wherein the first wiring includes a first wiring via and a first wiring line, wherein the first wiring structure includes a first layer, a second layer, and a third layer, wherein the first wiring via is in each of the first layer, the second layer, and the third layer, the first wiring via in the first layer, the first wiring via included in the second layer, and the first wiring via in the third layer contact each other in the vertical direction, wherein a size of the first wiring via in the first layer is different from a size of the first wiring via in the second layer, a size of the first wiring via in the second layer is different from a size of the third wiring via in the third layer, wherein the second wiring includes a second wiring via and a second wiring line, wherein the second wiring structure includes a first layer, a second layer, and a third layer, wherein the second wiring via is in each of the first layer, the second layer, and the third layer, the second wiring via in the first layer, the second wiring via in the second layer, and the second wiring via in the third layer contact each other in the vertical direction, wherein a size of the second wiring via in the first layer is smaller than a size of the second wiring via in the second layer, a size of the second wiring via in the second layer is smaller than a size of the third wiring via in the third layer, and wherein each of the first wiring via and the second wiring via includes a dimple recessed downward in the vertical direction from a top surface of each of the first wiring via and the second wiring via.

### BRIEF DESCRIPTION OF DRAWINGS

Embodiments will be more clearly understood from the following detailed description taken in conjunction with the accompanying drawings in which:

FIG. 1 is a cross-sectional view of a semiconductor package according to one or more embodiments;

FIG. 2 is an enlarged view illustrating an example of a portion AA of FIG. 1;

FIG. 3 is an enlarged view illustrating another example of the portion AA of FIG. 1;

FIG. 4 is a cross-sectional view of a semiconductor package according to one or more other embodiments;

FIG. 5 is an enlarged view illustrating an example of a portion AA of FIG. 4;

FIG. 6 is an enlarged view illustrating another example of the portion AA of FIG. 4;

FIG. 7 is an enlarged view illustrating an example of a portion BB of FIG. 4;

FIG. 8 is an enlarged view illustrating another example of the portion BB of FIG. 4;

FIG. 9 is a cross-sectional view of a semiconductor package according to another embodiment;

FIG. 10 is an enlarged view illustrating an example of a portion AA of FIG. 9;

FIG. 11 is an enlarged view illustrating another example of the portion AA of FIG. 9;

FIG. 12 is an enlarged view illustrating an example of a portion BB of FIG. 9; and

FIG. 13 is an enlarged view illustrating another example of the portion BB of FIG. 9.

### DETAILED DESCRIPTION

Hereinafter, embodiments will be described in detail with reference to the accompanying drawings. The same reference numerals are used for the same components in the drawings, and redundant descriptions thereof will be omitted. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

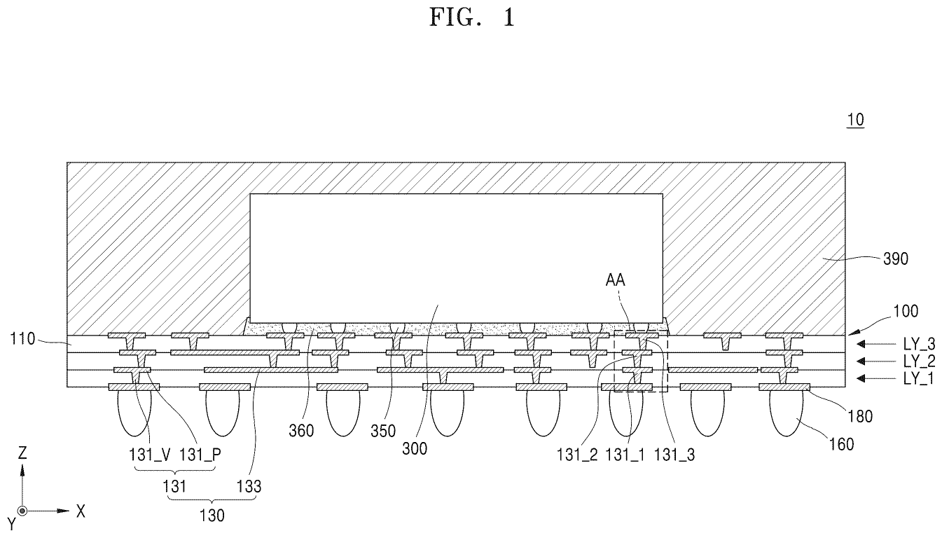

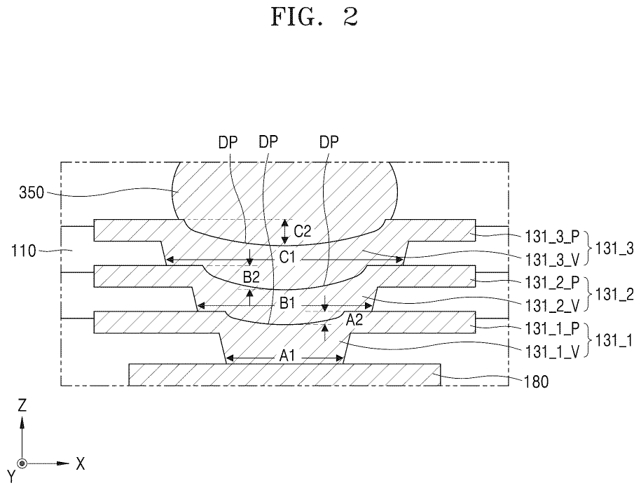

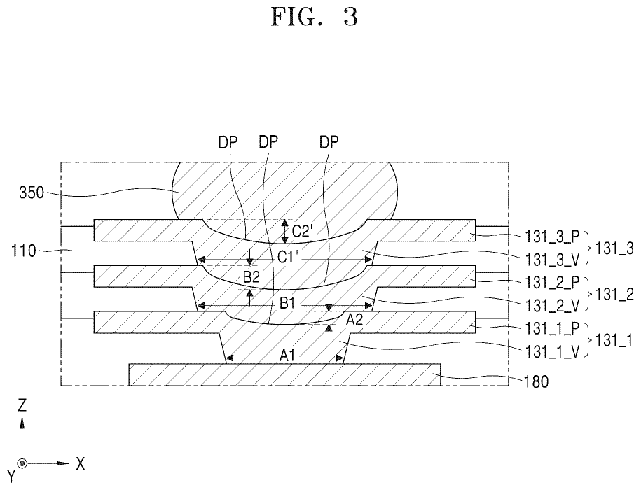

FIG. 1 is a cross-sectional view of a semiconductor package according to one or more embodiments. FIG. 2 is an enlarged view illustrating an example of a portion AA of FIG. 1. FIG. 3 is an enlarged view illustrating another example of the portion AA of FIG. 1.

Referring to FIGS. 1 to 3, a semiconductor package 10 according to one or more embodiments may include a first wiring structure 100, a first semiconductor chip 300, chip connection bumps 350, an underfill material layer 360, external connection bumps 160, and a molding member 390.

The first wiring structure 100 may include a top surface and a bottom surface opposite to each other, and at least one of the top and bottom surfaces may be a flat surface. The first wiring structure 100 may be arranged under the first semiconductor chip 300 in a vertical direction (Z-axis direction) and may electrically connect the first semiconductor chip 300 to the external connection bumps 160. The first wiring structure 100 may include a first wiring insulating layer 110 and a first wiring 130.

The first wiring insulating layer 110 may be provided with a plurality of layers stacked in one direction. For example, the first wiring insulating layer 110 may include a plurality of insulating layers stacked in the vertical direction (Z-axis direction). The first wiring 130 may include a plurality of patterns formed in the stacked insulating layers.

In the following drawings, a direction in which the plurality of insulating layers are stacked may be understood as a Z-axis direction, and an X-axis direction and a Y-axis direction may be perpendicular to each other in a plane having the Z-axis direction as a normal vector. That is, the X-axis direction and the Y-axis direction represent directions parallel to the surface of the top or bottom plane of the first wiring structure 100, and the X-axis direction and the Y-axis direction may be perpendicular to each other. In addition, in the following drawings, a first horizontal direction, a second horizontal direction, and a vertical direction may be understood as follows. The first horizontal direction may be understood as an X-axis direction, the second horizontal direction may be understood as a Y-axis direction, and the vertical direction may be understood as a Z-axis direction.

The first wiring 130 may be electrically and/or physically connected to each of the first semiconductor chip 300 and the external connection bumps 160. The first wiring 130 may include a first wiring via 131 and a first wiring line 133. The first wiring line 133 may have a shape extending in the first horizontal direction X in the first wiring insulating layer 110. According to one or more embodiments, the first wiring line 133 may be provided in each of a plurality of first wiring insulating layers 110 stacked in the vertical direction Z. The first wiring via 131 may include a first wiring via pattern 131_V and a first wiring via pad 131_P. The first wiring via pattern 131_V may extend in the vertical direction Z and penetrate the first wiring insulating layer 110 in the vertical direction Z. The first wiring via pad 131_P may be formed on the first wiring via pattern 131_V and may have a shape extending in a first horizontal direction X in the first wiring insulating layer 110. A horizontal width of the first wiring via pad 131_P may be less than a horizontal width of the first wiring line 133 in the horizontal direction(s) X and/or Y. According to embodiments, the first wiring via pad 131_P may be located at substantially the same vertical level as the first wiring line 133 in the vertical direction Z. According to embodiments, the first wiring via pattern 131_V may be formed together with the first wiring via pad 131_P to be integrally formed.

The first wiring via 131 may be electrically and/or physically connected to the first wiring via 131 formed on each of the different first wiring insulating layers 110. According to one or more embodiments, the plurality of first wiring vias 131 are located on different layers in the first wiring structure 100, but may be arranged while being in contact with each other in the vertical direction Z. For example, as shown in FIGS. 2 and 3, a first wiring via 131_1 located in a first layer LY_1, a first wiring via 131_2 located in a second layer LY_2, and a first wiring via 131_3 located in a third layer LY_3 may be in contact with each other in the vertical direction Z in turn and may be electrically and/or physically connected to each other. In this case, the first wiring vias 131_1, 131_2, and 131_3, which are in contact with each other in the vertical direction Z, may be understood as stack vias. In addition, according to one or more embodiments, the first wiring via 131 may be arranged while being in contact with the first wiring line 133 located below in the vertical direction Z within the first wiring structure 100. In this case, the first wiring via 131 may be a non-stack via.

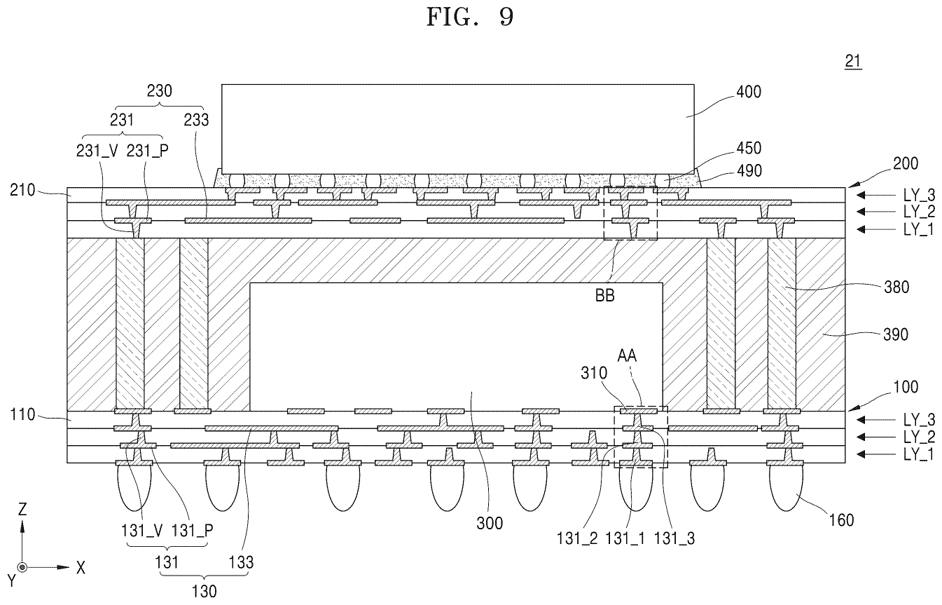

In one or more embodiments, the first wiring via pattern 131_V may have a tapered shape having a horizontal width in the horizontal direction(s) X and/or Y widening and extending from a lower side to an upper side thereof. For example, the horizontal width of the first wiring via pattern 131_V in the horizontal direction(s) X and/or Y may increase toward the first semiconductor chip 300. However, the shape of the first wiring via pattern 131_V is not limited thereto, and as illustrated in FIGS. 9 to 11, the first wiring via pattern 131_V may have a tapered shape in which a horizontal width in the horizontal direction(s) X and/or Y increases as a level in the vertical direction Z decreases.

According to one or more embodiments, as illustrated in FIGS. 2 and 3, a size of the first wiring via 131_1 located in the first layer LY_1 may be less than a size of the first wiring via 131_2 located in the second layer LY_2. For example, a horizontal width A1 of the lowermost surface of the first wiring via pattern 131_1_V of the first wiring via 131_1 located in the first layer LY_1 may be less than a horizontal width B1 of the lowermost surface of the first wiring via pattern 131_2_V of the first wiring via 131_2 located in the second layer LY_2. According to one or more embodiments, the horizontal width A1 of a lowermost surface of the first wiring via pattern 131_1_V of the first wiring via 131_1 located in the first layer LY_1 may be in a range of about 5 μm to about 20 μm. In addition, the horizontal width B1 of the lowermost surface of the first wiring via pattern 131_2_V of the first wiring via 131_2 located in the second layer LY_2 may be in a range of about 22 μm to about 30 μm.

According to one or more embodiments, a dimple DP may be formed on each of the first wiring vias 131_1, 131_2, and 131_3 located in the first to third layers LY_1, LY_2, and LY_3. The dimple DP may be a recess formed downward in the vertical direction Z from the top surface of the first wiring via pad 131_P. A cross section along the X-Z plane of a region in which the dimple DP is formed in each of the first wiring vias 131_1, 131_2, and 131_3 may have a downwardly convex curved shape. According to one or more embodiments, the horizontal width of the dimple DP may decrease as the vertical level of the dimple DP decreases. The first wiring via pattern 131_2_V located in the second layer LY_2 may be filled in the dimple DP of the first wiring via 131_1 located in the first layer LY_1. In addition, the dimple DP of the first wiring via 131_2 located in the second layer LY_2 may be filled with the first wiring via pattern 131_3_V located in the third layer LY_3. A chip connection bump 350 may be filled in the dimple DP of the first wiring via 131_3 located on the third layer LY_3.

In this example, a depth A2 of the dimple DP of the first wiring via 131_1 located in the first layer LY_1 may be less than a depth B2 of the dimple DP of the first wiring via 131_2 located in the second layer LY_2. In addition, a maximum horizontal width of the dimple DP of the first wiring via 131_1 located in the first layer LY_1 may be less than a maximum horizontal width of the dimple DP of the first wiring via 131_2 located in the second layer LY_2. The maximum horizontal width may be a horizontal width of a portion located at the same vertical level as the top surface of the first wiring via pad 131_P in a region where the dimple DP is formed.

According to one or more embodiments, the depth A2 of the dimple DP of the first wiring via 131_1 located in the first layer LY_1 may be in a range of about 1 μm to about 3 μm. In addition, the depth B2 of the dimple DP of the first wiring via 131_2 located in the second layer LY_2 may be in a range of about 5 μm to about 9 μm. When the depth A2 of the dimple DP of the first wiring via 131_1 located in the first layer LY_1 and the depth B2 of the dimple DP of the first wiring via 131_2 located in the second layer LY_2 are within the ranges described above, the dimple DP formed in the first wiring via pad 131_1_P located in the first layer LY_1 may be filled without gaps with the first wiring via pattern 131_2_V located in the second layer LY_2. Accordingly, the first wiring insulating layer 110 may not penetrate between the first wiring via pad 131_1_P located in the first layer LY_1 and the first wiring via pattern 131_2_V located in the second layer LY_2. The first wiring insulating layer 110 may be separate from the dimple DP formed on each of the first wiring vias 131_1, 131_2, and 131_3.

In some embodiments, as illustrated in FIG. 2, a size of the first wiring via 131_2 located in the second layer LY_2 may be less than the size of the first wiring via 131_3 located in the third layer LY_3. For example, a horizontal width B1 of a lowermost surface of the first wiring via pattern 131_2_V of the first wiring via 131_2 located in the second layer LY_2 may be less than a horizontal width C1 of a lowermost surface of the first wiring via pattern 131_3_V of the first wiring via 131_3 located in the third layer LY_3. In addition, a depth B2 of the dimple DP of the first wiring via 131_2 located in the second layer LY_2 may be less than a depth C2 of the dimple DP of the first wiring via 131_3 located in the third layer LY_3. In addition, a maximum horizontal width of the dimple DP of the first wiring via 131_2 located in the second layer LY_2 may be less than a maximum horizontal width of the dimple DP of the first wiring via 131_3 located in the third layer LY_3.

In one or more embodiments, as illustrated in FIG. 3, a size of the first wiring via 131_2 located in the second layer LY_2 may be substantially the same as a size of the first wiring via 131_3 located in the third layer LY_3. In this example, the horizontal width B1 of a lowermost surface of the first wiring via pattern 131_2_V of the first wiring via 131_2 located in the second layer LY_2 may be substantially the same as a horizontal width C1′ of a lowermost surface of the first wiring via pattern 131_3_V of the first wiring via 131_3 located in the third layer LY_3. In addition, the depth B2 of the dimple DP of the first wiring via 131_2 located in the second layer LY_2 may be substantially the same as a depth C2′ of the dimple DP of the first wiring via 131_3 located in the third layer LY_3.

In one or more embodiments, the first wiring structure 100 may be a redistribution structure manufactured through a redistribution process. In this example, the first wiring insulating layer 110 may include, for example, photo imageable dielectric (PID) or photosensitive polyimide (PSPI), and the first wiring 130 may be, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru) or the like, or a metal alloy thereof, but is not limited thereto. In one or more embodiments, the first wiring 130 may be formed by stacking a metal or an alloy of metal on a seed layer including copper, titanium, titanium nitride, or titanium tungsten.

As described above, when the first wiring structure 100 is a redistribution structure manufactured through a redistribution process, the first wiring 130 may be a redistribution pattern, and the first wiring insulating layer 110 may be a redistribution insulating layer.

In one or more embodiments, the first wiring structure 100 may be a printed circuit board (PCB). In this example, the first wiring insulating layer 110 may include at least one of phenol resin, epoxy resin, and polyimide. The first wiring insulating layer 110 may include at least one of, for example, frame retardant 4 (FR-4), tetrafunctional epoxy, polyphenylene ether, epoxy/polyphenylene oxide, bismaleimide triazine (BT), thermount, cyanate ester, polyimide, and liquid crystal polymer. In addition, the first wiring 130 may include copper, nickel, stainless steel, or beryllium copper.

The external connection bumps 160 may be located under the first wiring structure 100. The external connection bumps 160 may be electrically and/or physically connected to an external device, for example, a mother board. The external connection bumps 160 may be electrically and/or physically connected to the first wiring 130. The external connection bump 160 may transmit an electrical signal transmitted from the first semiconductor chip 300 to an external device through the first wiring 130. The first wiring 130 may be electrically and/or physically connected to an external device through an external connection bumps 160. The external connection bump 160 may include at least one of conductive materials, for example, solder, tin (Sn), silver (Ag), copper (Cu), and aluminum (Al).

The first semiconductor chip 300 may be mounted on a top surface of the first wiring structure 100. The first semiconductor chip 300 may be electrically and/or physically connected to the first wiring 130. According to one or more embodiments, the first semiconductor chip 300 may be mounted on the first wiring structure 100 in a flip chip manner through chip connection bumps 350 such as microbumps. For example, the chip connection bumps 350 may be between the first semiconductor chip 300 and the first wiring structure 100. According to one or more embodiments, an underfill material layer 360 provided on and surrounding the chip connection bumps 350 may be arranged between the first semiconductor chip 300 and the first wiring structure 100. The under-fill material layer 360 may include, for example, epoxy resin formed by a capillary under-fill method. However, embodiments are not limited thereto, and, for example, the molding member 390 may be filled directly into a gap between the first semiconductor chip 300 and the first wiring structure 100 through a molded under-fill process. In this example, the underfill material layer 360 may be omitted.

The first semiconductor chip 300 may include a memory chip or a logic chip. The memory chip may be, for example, a volatile memory chip such as dynamic random-access memory (DRAM) or static random-access memory (SRAM), or may be a nonvolatile memory chip, such as parallel random-access memory (PRAM), magnetoresistive random-access memory (MRAM), ferroelectrid random-access memory (FeRAM), or resistive random-access memory (RRAM). The logic chip may include, for example, a central processing unit (CPU), a graphic processing unit (GPU), a microprocessor such as an application processor (AP), an analog device, or a digital signal processor.

The molding member 390 may be formed to be provided on and surround the first semiconductor chip 300 on the top surface of the first wiring structure 100. In one or more embodiments, the molding member 390 may be provided on and cover a side surface of the first semiconductor chip 300, and a top surface of the molding member 390 and a top surface of the first semiconductor chip 300 may be coplanar. However, the shape of the molding member 390 is not limited thereto, and in one or more other embodiments, the molding member 390 may be provided on and cover the side surface and the top surface of the first semiconductor chip 300. In this example, a vertical level of the top surface of the molding member 390 may be higher than a vertical level of the top surface of the first semiconductor chip 300.

The molding member 390 may include a thermosetting resin such as an epoxy resin, a thermoplastic resin such as polyimide, or a resin including a reinforcing material such as an inorganic filler therein, For example, Ajinomoto build-up film (ABF), FR-4, BT, etc., but is not limited thereto, and the molding member 390 may include a molding material such as an epoxy mold compound (EMC) or a photosensitive material such as a photomagnetic encapsulant (PIE). In one or more embodiments, a portion of the first molding member 290 may include an insulating material such as, for example, a silicon oxide layer, a silicon nitride layer, or a silicon oxynitride layer.

In a region where a stack via is formed in the first wiring structure 100, the plurality of first wiring vias 131_1, 131_2, and 131_3 have the same size in related art. In addition, dimples DP may be formed in the first wiring vias 131_1, 131_2, and 131_3. However, when the first wiring vias 131_1, 131_2, and 131_3 having the same size are formed, and when the first wiring via pattern 131_V is filled on the dimple DP formed in the first wiring via 131, the first wiring insulating layer 110 remains on the dimple DP, and there may be a connection problem between the first wiring via pattern 131_V and the first wiring via pad 131_P located under the first wiring via pattern 131_V.

For example, in the process, the first wiring insulating layer 110 is filled in the dimple DP of the first wiring via pad 131_P located below, and the first wiring via pattern 131_V is filled in the dimple DP after the first wiring insulating layer 110 is etched. In this example, the first wiring insulating layer 110 may remain in the dimple DP, causing a connection problem between the first wiring via pad 131_P and the first wiring via pattern 131_V.

However, in the semiconductor package 10 according to one or more embodiments, since the size of the first wiring via 131_1 located in the first layer LY_1 in the region where the stack via is formed in the first wiring structure 100 is less than the size of the first wiring via 131_2 located in the second layer LY_2, the dimple DP of the first wiring via 131_1 located in the first layer LY_1 may also be less than the dimple DP of the first wiring via 131_2 located in the second layer LY_2. In addition, the size of the first wiring via pattern 131_2_V located in the second layer LY_2 may be greater than the size of the first wiring via pattern 131_1_V located in the first layer LY_1. Accordingly, the first wiring insulating layer 110 filled in the dimple DP of the first wiring via 131_1 located in the first layer LY_1 may be more easily removed, and a connection failure between the first wiring via pad 131_1_P located in the first layer LY_1 and the first wiring via pattern 131_2_V located in the second layer LY_2 may be omitted.

The first wiring insulating layer 110 may not be placed between the first wiring via pad 131_1_P located in the first layer LY_1 and the first wiring via pattern 131_2_V located in the second layer LY_2.

In addition, when the first wiring structure 100 includes the first to third layers LY_1, LY_2, and LY_3, as shown in FIG. 2, since the first wiring via 131_3 located in the third layer LY_3 is formed to be greater than the first wiring via 131_2 located in the second layer LY_2, the first wiring via pad 131_2_P located in the second layer LY_2 and the first wiring via pattern 131_3_V located in the third layer LY_3 may be more smoothly connected.

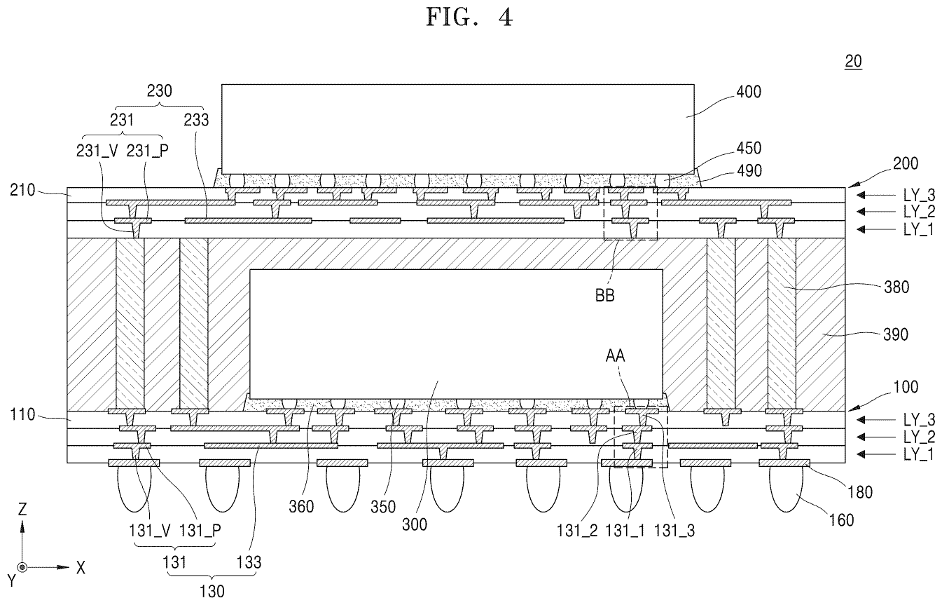

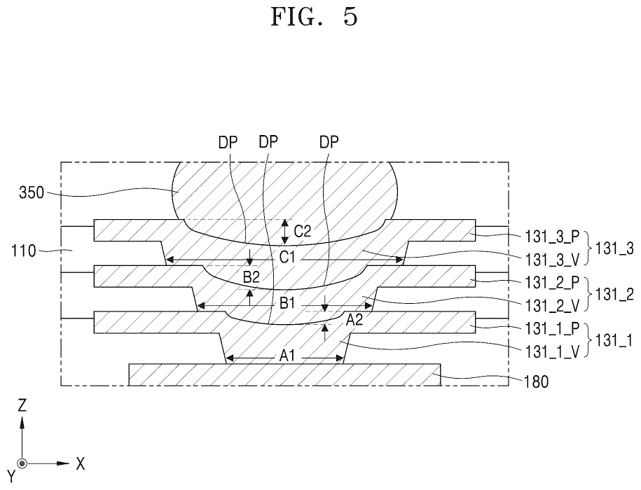

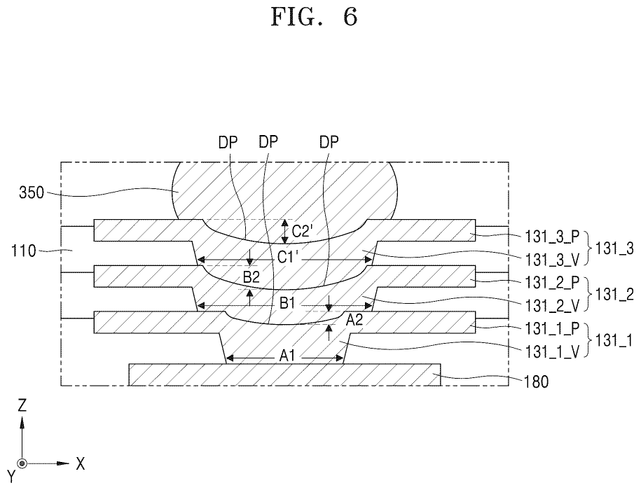

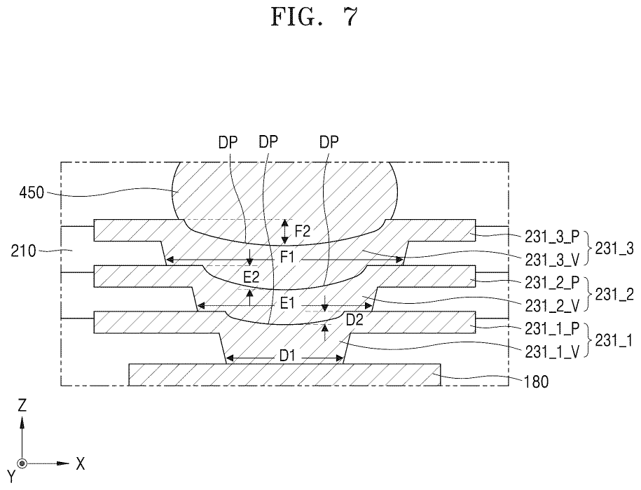

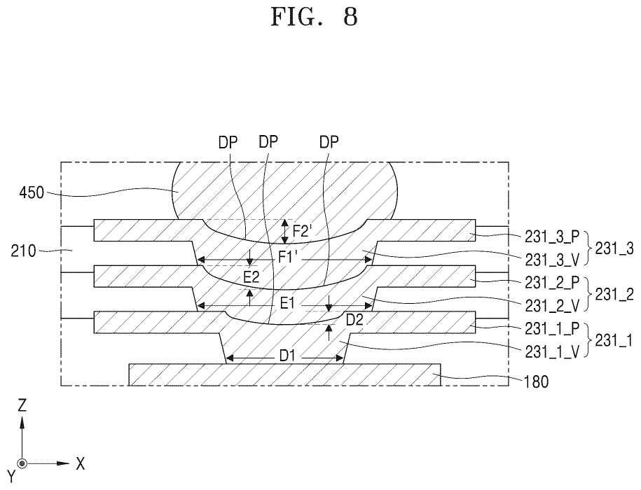

FIG. 4 is a cross-sectional view of a semiconductor package according to another embodiment. FIG. 5 is an enlarged view illustrating an example of a portion AA of FIG. 4. FIG. 6 is an enlarged view illustrating another example of the portion AA of FIG. 4. FIG. 7 is an enlarged view illustrating an example of a portion BB of FIG. 4. FIG. 8 is an enlarged view illustrating another example of the portion BB of FIG. 4. Hereinafter, descriptions overlapping with those described with reference to FIGS. 1 to 3 are omitted, and differences are mainly described.

Referring to FIGS. 4 to 8, a semiconductor package 20 according to one or more embodiments may include a first wiring structure 100, a first semiconductor chip 300, a second wiring structure 200, conductive pillars 380, a molding member 390, and a second semiconductor chip 400. The first wiring structure 100 may include a top surface and a bottom surface opposite to each other, and at least one of the top and bottom surfaces may be a flat surface. The first wiring structure 100 may be arranged under the first semiconductor chip 300 and may electrically connect the first semiconductor chip 300 to external connection bumps 160. The first wiring structure 100 may include a first wiring insulating layer 110 and a first wiring 130.

The first wiring 130 may include a first wiring via 131 and a first wiring line 133. The first wiring line 133 may have a shape extending in the first horizontal direction X in the first wiring insulating layer 110. According to one or more embodiments, the first wiring line 133 may be provided in each of a plurality of first wiring insulating layers 110 stacked in the vertical direction Z. The first wiring via 131 may include a first wiring via pattern 131_V and a first wiring via pad 131_P. The first wiring via pattern 131_V may extend in the vertical direction Z and penetrate the first wiring insulating layer 110 in the vertical direction Z. The first wiring via pad 131_P may be formed on the first wiring via pattern 131_V and may have a shape extending in a first horizontal direction X in the first wiring insulating layer 110. A horizontal width of the first wiring via pad 131_P may be less than a horizontal width of the first wiring line 133. According to one or more embodiments, the first wiring via pad 131_P may be located at substantially the same vertical level as the first wiring line 133. According to one or more embodiments, the first wiring via pattern 131_V may be formed together with the first wiring via pad 131_P to be integrally formed.

According to one or more embodiments, as illustrated in FIGS. 5 and 6, a size of the first wiring via 131_1 located in the first layer LY_1 may be less than a size of the first wiring via 131_2 located in the second layer LY_2. For example, a horizontal width A1 of the lowermost surface of the first wiring via pattern 131_1_V of the first wiring via 131_1 located in the first layer LY_1 may be less than a horizontal width B1 of the lowermost surface of the first wiring via pattern 131_2_V of the first wiring via 131_2 located in the second layer LY_2.

According to one or more embodiments, a dimple DP may be formed on each of the first wiring vias 131_1, 131_2, and 131_3 located in the first to third layers LY_1, LY_2, and LY_3.

According to one or more embodiments, a depth A2 of the dimple DP of the first wiring via 131_1 located in the first layer LY_1 may be less than a depth B2 of the dimple DP of the first wiring via 131_2 located in the second layer LY_2. In addition, a maximum horizontal width of the dimple DP of the first wiring via 131_1 located in the first layer LY_1 may be less than a maximum horizontal width of the dimple DP of the first wiring via 131_2 located in the second layer LY_2. The description described with reference to FIGS. 5 and 6 is substantially the same as the description described with reference to FIGS. 1 and 2, and thus a detailed description thereof will be omitted.

In one or more embodiments, as illustrated in FIG. 4, a size of the first wiring via 131_2 located in the second layer LY_2 may be less than the size of the first wiring via 131_3 located in the third layer LY_3. In some embodiments, as illustrated in FIG. 5, a size of the first wiring via 131_2 located in the second layer LY_2 may be substantially the same as a size of the first wiring via 131_3 located in the third layer LY_3. The description described with reference to FIGS. 4 and 6 is substantially the same as the description described with reference to FIGS. 1 and 3, and thus a detailed description thereof will be omitted.

The first semiconductor chip 300 may be mounted on a top surface of the first wiring structure 100. The first semiconductor chip 300 may be electrically and/or physically connected to the first wiring 130. According to one or more embodiments, the first semiconductor chip 300 may be mounted on the first wiring structure 100 in a flip chip manner through chip connection bumps 350 such as microbumps. For example, the chip connection bumps 350 may be between the first semiconductor chip 300 and the first wiring structure 100. According to one or more embodiments, an underfill material layer 360 provided on and surrounding the chip connection bumps 350 may be arranged between the first semiconductor chip 300 and the first wiring structure 100.

Each of the conductive pillars 380 may be provided on the first wiring structure 100 to be spaced apart from the first semiconductor chip 300 in the horizontal direction(s) X or/and Y. Each of the conductive pillars 380 may extend in the vertical direction Z through the molding member 390. Each of the conductive pillars may be, for example, a through mold via or a conductive post. Each of the conductive pillars may include, for example, copper (Cu). Each of the conductive pillars 380 may be a vertical connection conductor for electrically connecting the second wiring structure 200 with the first wiring structure 100.

The second wiring structure 200 may be located on the molding member 390 and the conductive pillars 380. The second wiring structure 200 may include a top surface and a bottom surface opposite to each other, and at least one of the top and bottom surfaces may be a flat surface. The second wiring structure 200 may include a second wiring 230 and a second wiring insulating layer 210. The second wiring 230 may include a second wiring via 231 and a second wiring line 233. The second wiring line 233 may have a shape extending in the first horizontal direction X within the second wiring insulating layer 210. The second wiring via 231 may include a second wiring via pattern 231_V and a second wiring via pad 231_P.

The second wiring via pattern 231_V may extend in the vertical direction Z and penetrate the second wiring insulating layer 210 in the vertical direction Z. The second wiring via pad 231_P is formed on the second wiring via pattern 231_V, and may have a shape extending in the second horizontal direction X within the second wiring insulating layer 210. A horizontal width of the second wiring via pad 231_P may be less than a horizontal width of the second wiring line 233. According to one or more embodiments, the second wiring via pad 231_P may be located at substantially the same vertical level as the second wiring line 233. According to one or more embodiments, the second wiring via pattern 231_V may be formed together with the second wiring via pad 231_P to be integrally formed.

According to one or more embodiments, a plurality of second wiring vias 231 are located on different layers in the second wiring structure 200, but may be arranged while being in contact with each other along the vertical direction Z. For example, as shown in FIGS. 7 and 8, the second wiring via 231_1 located in the first layer LY_1, the second wiring via 231_2 located in the second layer LY_2, and the second wiring via 231_3 located in the third layer LY_3 are in contact with each other in the vertical direction Z in turn and may be electrically and/or physically connected to each other. In this example, the second wiring vias 231_1, 231_2, and 231_3, which are in contact with each other in the vertical direction Z, may be understood as stack vias. In addition, according to one or more embodiments, the second wiring via 231 may be arranged while being in contact with the second wiring line 233 located below in the vertical direction Z within the second wiring structure 200. In this example, the second wiring via 231 may be a non-stack via.

In one or more embodiments, the second wiring via pattern 231_V may have a tapered shape having a horizontal width increasing and extending from a lower side to an upper side of the second wiring via pattern 231_V in the vertical direction Z. For example, the horizontal width of the second wiring via pattern 231_V may increase toward the second semiconductor chip 400.

According to one or more embodiments, as illustrated in FIGS. 7 and 8, a size of the second wiring via 231_1 located in the first layer LY_1 may be less than a size of the second wiring via 231_2 located in the second layer LY_2. For example, a horizontal width D1 of the lowermost surface of the second wiring via pattern 231_1_V of the second wiring via 231_1 located in the first layer LY_1 may be less than a horizontal width E1 of the lowermost surface of the second wiring via pattern 231_2_V of the second wiring via 231_2 located in the second layer LY_2. According to one or more embodiments, the horizontal width D1 of a lowermost surface of the second wiring via pattern 231_1_V of the second wiring via 231_1 located in the first layer LY_1 may be in a range of about 5 μm to about 20 μm. In addition, the horizontal width E1 of the lowermost surface of the second wiring via pattern 231_2_V of the second wiring via 231_2 located in the second layer LY_2 may be in a range of about 22 μm to about 30 μm.

According to one or more embodiments, a dimple DP may be formed on each of the second wiring vias 231_1, 231_2, and 231_3 located on the first to third layers LY_1, LY_2, and LY_3. The dimple DP may be a recess formed downward in the vertical direction Z from the top surface of the second wiring via pad 231_P. A cross section along the X-Z plane of a region in which the dimple DP is formed in each of the second wiring vias 231_1, 231_2, and 231_3 may have a downwardly convex curved shape. According to one or more embodiments, the horizontal width of the dimple DP may have a shape that decreases as the vertical level decreases. The second wiring via pattern 231_2_V located in the second layer LY_2 may be filled in the dimple DP of the second wiring via 231_1 located in the first layer LY_1. In addition, the dimple DP of the second wiring via 231_2 located in the second layer LY_2 may be filled with the second wiring via pattern 231_3_V located in the third layer LY_3. A chip connection bump 450 may be filled in the dimple DP of the second wiring via 231_3 located on the third layer LY_3.

In this example, a depth D2 of the dimple DP of the second wiring via 231_1 located in the first layer LY_1 may be less than a depth E2 of the dimple DP of the second wiring via 231_2 located in the second layer LY_2. In addition, a maximum horizontal width of the dimple DP of the second wiring via 231_1 located in the first layer LY_1 may be less than a maximum horizontal width of the dimple DP of the second wiring via 231_2 located in the second layer LY_2. The maximum horizontal width may be a horizontal width of a portion located at the same vertical level as the top surface of the second wiring via pad 231_P in a region where the dimple DP is formed.

According to one or more embodiments, the depth A2 of the dimple DP of the second wiring via 231_1 located in the first layer LY_1 may be in a range of about 1 μm to about 3 μm. In addition, the depth E2 of the dimple DP of the second wiring via 231_2 located in the second layer LY_2 may be in a range of about 5 μm to about 9 μm. When the depth D2 of the dimple DP of the second wiring via 231_1 located in the first layer LY_1 and the depth E2 of the dimple DP of the second wiring via 231_2 located in the second layer LY_2 are within the ranges described above, the dimple DP formed in the second wiring via pad 231_1_P located in the first layer LY_1 may be filled without gaps with the second wiring via pattern 231_2_V located in the second layer LY_2. Accordingly, the second wiring insulating layer 210 may not penetrate between the second wiring via pad 231_1_P located in the first layer LY_1 and the second wiring via pattern 231_2_V located in the second layer LY_2.

In one or more embodiments, as illustrated in FIG. 7, a size of the second wiring via 231_2 located in the second layer LY_2 may be less than a size of the second wiring via 231_3 located in the third layer LY_3. For example, a horizontal width E1 of the lowermost surface of the second wiring via pattern 231_2_V of the second wiring via 231_2 located in the second layer LY_2 may be less than a horizontal width F1 of the lowermost surface of the second wiring via pattern 231_3_V of the second wiring via 231_3 located in the third layer LY_3. In addition, a depth E2 of the dimple DP of the second wiring via 231_2 located in the second layer LY_2 may be less than a depth F2 of the dimple DP of the second wiring via 231_3 located in the third layer LY_3. In addition, a maximum horizontal width of the dimple DP of the second wiring via 231_2 located in the second layer LY_2 may be less than a maximum horizontal width of the dimple DP of the second wiring via 231_3 located in the third layer LY_3.

In one or more embodiments, as illustrated in FIG. 8, a size of the second wiring via 231_2 located in the second layer LY_2 may be substantially the same as a size of the second wiring via 231_3 located in the third layer LY_3. In this example, the horizontal width E1 of the lowermost surface of the second wiring via pattern 231_2_V of the second wiring via 231_2 located in the second layer LY_2 may be substantially the same as a horizontal width F1′ of the lowermost surface of the second wiring via pattern 231_3_V of the second wiring via 231_3 located in the third layer LY_3. In addition, the depth E2 of the dimple DP of the second wiring via 231_2 located in the second layer LY_2 may be substantially the same as a depth F2′ of the dimple DP of the second wiring via 231_3 located in the third layer LY_3.

The second semiconductor chip 400 may be mounted on a top surface of the second wiring structure 200. The second semiconductor chip 400 may include a memory chip or a logic chip. According to one or more embodiments, the second semiconductor chip 400 may be mounted on the second wiring structure 200 in a flip chip manner through chip connection bumps 450 such as microbumps. For example, the chip connection bumps 450 may be between the second semiconductor chip 400 and the second wiring structure 200. According to one or more embodiments, an underfill material layer 460 provided on and surrounding the chip connection bumps 450 may be arranged between the second semiconductor chip 400 and the second wiring structure 200.

The semiconductor package 20 may include the first wiring structure 100 and the second wiring structure 200. In addition, since a size of the first wiring via 131_1 located in the first layer LY_1 in a region where a stack via is formed in the first wiring structure 100 is less than a size of the first wiring via 131_2 located in the second layer LY_2, and a size of the second wiring via 231_1 located in the first layer LY_1 in a region where a stack via is formed in the second wiring structure 200 is less than the size of the second wiring via 231_2 located in the second layer LY_2, a connection failure between the first wiring via pad 131_1_P located in the first layer LY_1 and the first wiring via pattern 131_2_V located in the second layer LY_2 may be omitted, and a connection failure between the second wiring via pad 231_1_P located in the first layer LY_1 and the second wiring via pattern 231_2_V located in the second layer LY_2 may be omitted.

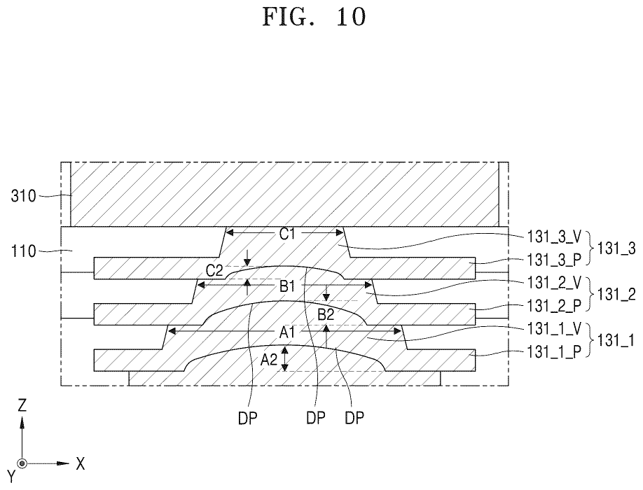

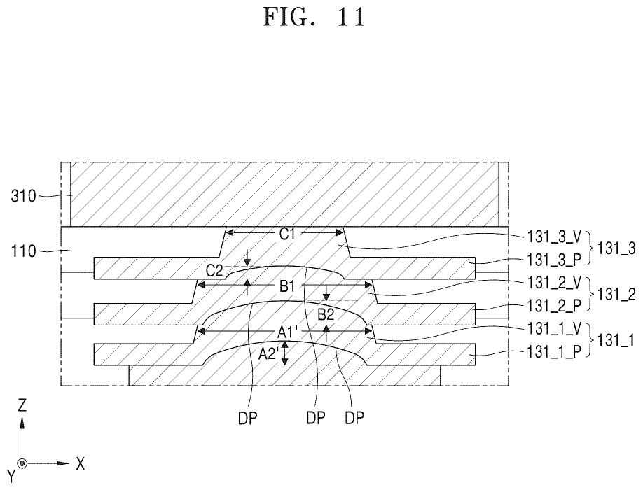

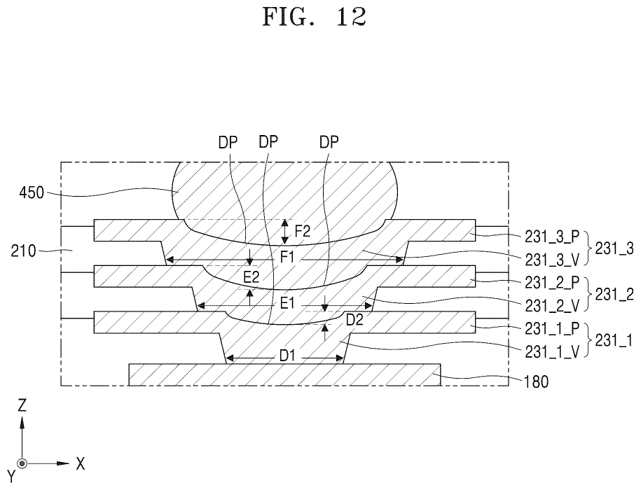

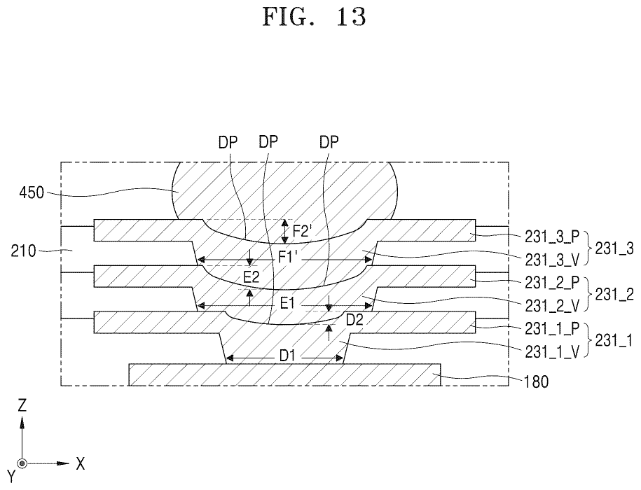

FIG. 9 is a cross-sectional view of a semiconductor package according to one or more other embodiments. FIG. 10 is an enlarged view illustrating an example of a portion AA of FIG. 9. FIG. 11 is an enlarged view illustrating another example of the portion AA of FIG. 9. FIG. 12 is an enlarged view illustrating an example of a portion BB of FIG. 9. FIG. 13 is an enlarged view illustrating another example of the portion BB of FIG. 9. Hereinafter, descriptions overlapping with those described with reference to FIGS. 4 to 8 are omitted, and differences are mainly described.

Referring to FIGS. 9 to 13, a semiconductor package 21 according to one or more embodiments may include a first wiring structure 100, a first semiconductor chip 300, a second wiring structure 200, conductive pillars 380, a molding member 390, and a second semiconductor chip 400.

The first wiring structure 100 may include a top surface and a bottom surface opposite to each other, and at least one of the top and bottom surfaces may be a flat surface. The first wiring structure 100 may be arranged under the first semiconductor chip 300 and may electrically connect the first semiconductor chip 300 to the external connection bumps 160. The first wiring structure 100 may include a first wiring insulating layer 110 and a first wiring 130.

The first wiring 130 may include a first wiring via 131 and a first wiring line 133. The first wiring line 133 may have a shape extending in the first horizontal direction X in the first wiring insulating layer 110. According to one or more embodiments, the first wiring line 133 may be provided in each of a plurality of first wiring insulating layers 110 stacked in the vertical direction Z. The first wiring via 131 may include a first wiring via pattern 131_V and a first wiring via pad 131_P. The first wiring via pattern 131_V may extend in the vertical direction Z and penetrate the first wiring insulating layer 110 in the vertical direction Z. The first wiring via pad 131_P may be formed on the first wiring via pattern 131_V and may have a shape extending in a first horizontal direction X in the first wiring insulating layer 110.

According to one or more embodiments, a horizontal width of the first wiring via pattern 131_V may have a tapered shape that decreases as the vertical level increases. Similarly, a horizontal width of the first wiring via pattern 131_V may have a shape in which the horizontal width decreases toward the first semiconductor chip 300.

According to one or more embodiments, as illustrated in FIG. 10, a size of the first wiring via 131_1 located in the first layer LY_1 may be greater than a size of the first wiring via 131_2 located in the second layer LY_2. In addition, a size of the first wiring via 131_2 located in the second layer LY_2 may be greater than a size of the first wiring via 131_3 located in the third layer LY_3. For example, a horizontal width A1 of the lowermost surface of the first wiring via pattern 131_1_V of the first wiring via 131_1 located in the first layer LY_1 may be greater than a horizontal width B1 of the lowermost surface of the first wiring via pattern 131_2_V of the first wiring via 131_2 located in the second layer LY_2. In addition, a horizontal width B1 of a lowermost surface of the first wiring via pattern 131_2_V of the first wiring via 131_2 located in the second layer LY_2 may be greater than a horizontal width C1 of a lowermost surface of the first wiring via pattern 131_3_V of the first wiring via 131_3 located in the third layer LY_3. The first wiring vias 131_1, 131_2, and 131_3 illustrated in FIG. 10 may have shapes in which the first wiring vias 131_1, 131_2, and 131_3 illustrated in FIG. 2 are rotated by 180 degrees, which may be caused by a difference in whether the first wiring structure 100 is formed by a chip-first process or a chip-last process. For example, the first wiring vias 131_1, 131_2, and 131_3 shown in FIG. 10 may be one or more embodiments formed by the chip first process, and the first wiring vias 131_1, 131_2, and 131_3 shown in FIG. 2 may be one or more embodiments formed by the chip last process.

According to one or more embodiments, a dimple DP may be formed on each of the first wiring vias 131_1, 131_2, and 131_3 located in the first to third layers LY_1, LY_2, and LY_3.

According to one or more embodiments, a depth A2 of the dimple DP of the first wiring via 131_1 located in the first layer LY_1 may be greater than a depth B2 of the dimple DP of the first wiring via 131_2 located in the second layer LY_2. A depth B2 of the dimple DP of the first wiring via 131_2 located in the second layer LY_2 may be greater than a depth C2 of the dimple DP of the first wiring via 131_3 located in the third layer LY_3. In addition, a maximum horizontal width of the dimple DP of the first wiring via 131_1 located in the first layer LY_1 may be greater than a maximum horizontal width of the dimple DP of the first wiring via 131_2 located in the second layer LY_2. A maximum horizontal width of the dimple DP of the first wiring via 131_2 located in the second layer LY_2 may be greater than a maximum horizontal width of the dimple DP of the first wiring via 131_3 located in the third layer LY_3.

According to one or more embodiments, as illustrated in FIG. 11, a size of the first wiring via 131_1 located in the first layer LY_1 may be substantially the same as a size of the first wiring via 131_2 located in the second layer LY_2. A size of the first wiring via 131_2 located in the second layer LY_2 may be greater than a size of the first wiring via 131_3 located in the third layer LY_3. For example, a horizontal width A1 of the lowermost surface of the first wiring via pattern 131_1_V of the first wiring via 131_1 located in the first layer LY_1 may be substantially the same as a horizontal width B1 of the lowermost surface of the first wiring via pattern 131_2_V of the first wiring via 131_2 located in the second layer LY_2. A horizontal width B1 of a lowermost surface of the first wiring via pattern 131_2_V of the first wiring via 131_2 located in the second layer LY_2 may be greater than a horizontal width C1 of a lowermost surface of the first wiring via pattern 131_3_V of the first wiring via 131_3 located in the third layer LY_3. The first wiring vias 131_1, 131_2, and 131_3 illustrated in FIG. 11 may have shapes in which the first wiring vias 131_1, 131_2, and 131_3 illustrated in FIG. 3 are rotated by 180 degrees, which may be due to a difference in whether the first wiring structure 100 is formed by a chip first process or a chip last process. For example, the first wiring vias 131_1, 131_2, and 131_3 shown in FIG. 11 may be one or more embodiments formed by the chip first process, and the first wiring vias 131_1, 131_2, and 131_3 shown in FIG. 3 may be one or more embodiments formed by the chip last process.

According to one or more embodiments, a dimple DP may be formed on each of the first wiring vias 131_1, 131_2, and 131_3 located in the first to third layers LY_1, LY_2, and LY_3.

According to one or more embodiments, a depth A2′ of the dimple DP of the first wiring via 131_1 located in the first layer LY_1 may be substantially the same as a depth B2 of the dimple DP of the first wiring via 131_2 located in the second layer LY_2. In contrast, a depth B2 of the dimple DP of the first wiring via 131_2 located in the second layer LY_2 may be greater than a depth C2 of the dimple DP of the first wiring via 131_3 located in the third layer LY_3. In addition, a maximum horizontal width of the dimple DP of the first wiring via 131_1 located in the first layer LY_1 may be substantially the same as a maximum horizontal width of the dimple DP of the first wiring via 131_2 located in the second layer LY_2. In contrast, a maximum horizontal width of the dimple DP of the first wiring via 131_2 located in the second layer LY_2 may be greater than a maximum horizontal width of the dimple DP of the first wiring via 131_3 located in the third layer LY_3.

The first semiconductor chip 300 may be mounted on a top surface of the first wiring structure 100. The first semiconductor chip 300 may be electrically and/or physically connected to the first wiring 130. According to one or more embodiments, the first semiconductor chip 300 is electrically and/or physically connected to the first wiring 130 through the chip pad 310, and chip connection bumps may not be arranged between the first semiconductor chip 300 and the first wiring structure 100.

Each of the conductive pillars 380 may be provided on the first wiring structure 100 to be spaced apart from the first semiconductor chip 300 in the horizontal direction(s) X or/and Y. Each of the conductive pillars 380 may extend in the vertical direction Z through the molding member 390.

The second wiring structure 200 may be located on the molding member 390 and the conductive pillars 380. The second wiring structure 200 may include a top surface and a bottom surface opposite to each other, and at least one of the top and bottom surfaces may be a flat surface. The second wiring structure 200 may include a second wiring 230 and a second wiring insulating layer 210. The second wiring 230 may include a second wiring via 231 and a second wiring line 233. The second wiring line 233 may have a shape extending in the first horizontal direction X within the second wiring insulating layer 210. The second wiring via 231 may include a second wiring via pattern 231_V and a second wiring via pad 231_P. Since the second wiring structure 200 is substantially the same as that described with reference to FIGS. 4 to 8, a detailed description thereof is omitted.

The second semiconductor chip 400 may be mounted on a top surface of the second wiring structure 200. The second semiconductor chip 400 may include a memory chip or a logic chip. According to one or more embodiments, the second semiconductor chip 400 may be mounted on the second wiring structure 200 in a flip chip manner through chip connection bumps 450 such as microbumps. For example, the chip connection bumps 450 may be between the second semiconductor chip 400 and the second wiring structure 200. According to embodiments, an underfill material layer 460 provided on and surrounding the chip connection bumps 450 may be arranged between the second semiconductor chip 400 and the second wiring structure 200.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first wiring structure comprising a first wiring and a first wiring insulating layer surrounding the first wiring;
a first semiconductor chip on the first wiring structure; and
a molding member on the first semiconductor chip,
wherein the first wiring comprises a first wiring via and a first wiring line,
wherein the first wiring structure comprises a first layer and a second layer,
wherein the first wiring via is in each of the first layer and the second layer,
wherein the first wiring via in the first layer and the first wiring via in the second layer contact each other in a vertical direction, and
wherein a size of the first wiring via in the first layer is smaller than a size of the first wiring via in the second layer.

2. The semiconductor package of claim 1, wherein a chip connection bump and an underfill material layer on the chip connection bump are between the first wiring structure and the first semiconductor chip.

3. The semiconductor package of claim 1, wherein the first wiring via comprises a plurality of first wiring vias and the first wiring line comprises a plurality of first wiring lines, and
wherein some of the plurality of first wiring vias are in contact with other first wiring vias among the plurality of first wiring vias in different layers, and some of the plurality of first wiring vias are in contact with first wiring lines among the plurality of first wiring lines in different layers.

4. The semiconductor package of claim 1, wherein the first wiring via comprises a first wiring via pattern and a first wiring via pad, and
wherein a width of a lowermost surface of the first wiring via pattern of the first wiring via in the first layer is smaller than a width of a lowermost surface of the first wiring via pattern of the first wiring via in the second layer in a horizontal direction.

5. The semiconductor package of claim 4, wherein the width of the lowermost surface of the first wiring via pattern of the first wiring via in the first layer is in a range of 5 μm to 20 μm in the horizontal direction, and
wherein the width of the lowermost surface of the first wiring via pattern of the first wiring via in the second layer is in a range of 22 μm to 30 μm in the horizontal direction.

6. The semiconductor package of claim 1, wherein the first wiring via comprises a dimple recessed downward in the vertical direction from a top surface of the first wiring via.

7. The semiconductor package of claim 6, wherein a depth of the dimple of the first wiring via in the first layer is smaller than a depth of the dimple of the first wiring via in the second layer.

8. The semiconductor package of claim 7, wherein the depth of the dimple of the first wiring via in the first layer is in a range of 1 μm to 3 μm in the vertical direction, and
wherein the depth of the dimple of the first wiring via in the second layer is in a range of 5 μm to 9 μm in the vertical direction.

9. The semiconductor package of claim 1, wherein the first wiring via comprises a first wiring via pattern and a first wiring via pad, and
wherein the first wiring via pattern has a tapered shape in which a width of the first wiring via pattern in a horizontal direction increases as a vertical level of the first wiring via pattern increases.

10. The semiconductor package of claim 1, wherein the first wiring structure further comprises a third layer,
wherein the first wiring via is in the third layer, and
wherein a size of the first wiring via in the third layer is greater than a size of the first wiring via in the second layer.

11. The semiconductor package of claim 1, wherein the first wiring structure further comprises a third layer,
wherein the first wiring via is in the third layer, and
wherein a size of the first wiring via in the third layer is the same as a size of the first wiring via in the second layer.

12. A semiconductor package comprising:
a first wiring structure comprising a first wiring and a first wiring insulating layer surrounding the first wiring;
a first semiconductor chip on the first wiring structure;
a conductive pillar on the first wiring structure and extending in a vertical direction, the conductive pillar being spaced apart from the first semiconductor chip in a horizontal direction;
a molding member on the first semiconductor chip and the conductive pillar;
a second wiring structure on the molding member and comprising a second wiring and a second wiring insulating layer on the second wiring; and
a second semiconductor chip on the second wiring structure,
wherein the first wiring comprises a first wiring via and a first wiring line,
wherein the first wiring structure comprises a first layer and a second layer,
wherein the first wiring via is in each of the first layer and the second layer,
wherein the first wiring via in the first layer and the first wiring via in the second layer contact each other in the vertical direction,
wherein a size of the first wiring via in the first layer is different from a size of the first wiring via in the second layer,
wherein the second wiring comprises a second wiring via and a second wiring line,
wherein the second wiring structure comprises a first layer and a second layer,
wherein the second wiring via is in each of the first layer and the second layer,
wherein the second wiring via in the first layer and the second wiring via in the second layer contact each other in the vertical direction, and
wherein a size of the second wiring via in the first layer is smaller than a size of the second wiring via in the second layer.

13. The semiconductor package of claim 12, wherein a size of the first wiring via included in the first layer is smaller than a size of the first wiring via in the second layer.

14. The semiconductor package of claim 12, wherein a size of the first wiring via in the first layer is greater than a size of the first wiring via in the second layer, and
wherein at least a portion of the first wiring structure contacts the first semiconductor chip.

15. The semiconductor package of claim 14, wherein the first wiring via comprises a first wiring via pattern and a first wiring via pad, and
wherein the first wiring via pattern has a tapered shape in which a width of the first wiring via pattern decreases as a vertical level of the first wiring via pattern increases.

16. The semiconductor package of claim 12, wherein the first wiring via comprises a plurality of first wiring vias, the first wiring line comprises a plurality of first wiring lines, some of the plurality of first wiring vias are in contact with other first wiring vias among the plurality of first wiring vias on different layers, and some of the plurality of first wiring vias are in contact with first wiring lines among the plurality of first wiring lines in different layers, and
wherein the second wiring via comprises a plurality of second wiring vias, the second wiring line comprises a plurality of second wiring lines, some of the plurality of second wiring vias are in contact with other second wiring vias among the plurality of second wiring vias on different layers, and some of the plurality of second wiring vias are in contact with second wiring lines among the plurality of second wiring lines on different layers.

17. The semiconductor package of claim 12, wherein each of the first wiring via and the second wiring via comprises a dimple recessed downward in the vertical direction from a top surface of each of the first wiring via and the second wiring via, and
wherein the first wiring insulating layer and the second wiring insulating layer are separate from the dimple included in each of the first wiring via and the second wiring via.

18. A semiconductor package comprising:
a first wiring structure comprising a first wiring and a first wiring insulating layer surrounding the first wiring,
a first semiconductor chip on the first wiring structure,
a conductive pillar on the first wiring structure and extending in a vertical direction, the conductive pillar being spaced apart from the first semiconductor chip in a horizontal direction,
a molding member on the first semiconductor chip and the conductive pillar,
a second wiring structure on the molding member and comprising a second wiring and a second wiring insulating layer on the second wiring; and
a second semiconductor chip on the second wiring structure,
wherein the first wiring comprises a first wiring via and a first wiring line,
wherein the first wiring structure comprises a first layer, a second layer, and a third layer,
wherein the first wiring via is in each of the first layer, the second layer, and the third layer,
wherein the first wiring via in the first layer, the first wiring via in the second layer, and the first wiring via in the third layer contact each other in the vertical direction,
wherein a size of the first wiring via in the first layer is different from a size of the first wiring via in the second layer, and a size of the first wiring via in the second layer is different from a size of the third wiring via in the third layer,
wherein the second wiring comprises a second wiring via and a second wiring line,
wherein the second wiring structure comprises a first layer, a second layer, and a third layer,
wherein the second wiring via is in each of the first layer, the second layer, and the third layer,
wherein the second wiring via in the first layer, the second wiring via in the second layer, and the second wiring via in the third layer contact each other in the vertical direction,
wherein a size of the second wiring via in the first layer is smaller than a size of the second wiring via in the second layer, and a size of the second wiring via in the second layer is smaller than a size of the third wiring via in the third layer, and
wherein each of the first wiring via and the second wiring via comprises a dimple recessed downward in the vertical direction from a top surface of each of the first wiring via and the second wiring via.

19. The semiconductor package of claim 18, wherein a size of the first wiring via in the first layer is greater than a size of the first wiring via in the second layer, a size of the first wiring via in the second layer is greater than a size of the first wiring via in the third layer,
wherein at least a portion of the first wiring structure contacts the first semiconductor chip,
wherein the first wiring via comprises a first wiring via pattern and a first wiring via pad, and
wherein the first wiring via pattern has a tapered shape in which a width of the first wiring via pattern in the horizontal direction decreases as a level of the first wiring via pattern in the vertical direction increases.

20. The semiconductor package of claim 18, wherein a size of the first wiring via in the first layer is smaller than a size of the first wiring via in the second layer, and
wherein a size of the first wiring via in the second layer is smaller than a size of the first wiring via in the third layer.
